(19) United States
(12) Patent Application Publication
(10) Pub. No.: US 2007/0268749 A1
(43) Pub. Date: Nov. 22, 2007

(54) Method for operating non-volatile memory device

(76) Inventors: Dae-Mann Kim, Dongdaemun-gu (KR); Wook-Hyun Kwon, Yongin-si (KR); Ki-Nam Kim, Gangnam-gu (KR); Chan-Kwang Park, Gangnam-gu (KR); Sang-Pil Sim, Gangnam-gu (KR)

Correspondence Address: VOLENTINE & WHITT PLLC, ONE FREEDOM SQUARE, 11951 FREEDOM DRIVE SUITE 1260, RESTON, VA, 20190, US

(21) Appl. No.: 11/802,282

(22) Filed: May 22, 2007

(30) Foreign Application Priority Data
May 22, 2006 (KR) 10-2006-45798

(51) Int. Cl. G11C 11/34; G11C 16/04

(52) U.S. Cl. 365/185.18; 365/185.29; 365/185.3

(57) ABSTRACT

A method of operating a non-volatile memory device is disclosed. The memory cell includes a channel region separating a source region and a drain region, a tunnel insulating layer, a charge storage layer, and a gate electrode formed over the channel region. The method includes applying a negative voltage to the gate electrode and applying a positive voltage to at least one of the source and drain regions to inject holes into the tunnel insulating layer and thereby remove electrons trapped in the tunnel insulating layer.

### CROSS-REFERENCE TO RELATED APPLICATIONS

This U.S. non-provisional patent application claims priority under 35 U.S.C. §119 of Korean Patent Application No. 2006-45798, filed on May 22, 2006, the subject matter of which is hereby incorporated by reference.

### BACKGROUND OF THE INVENTION

1. Field of the Invention

The present invention relates to a method for operating a semiconductor device. More particularly, the invention relates to a more reliable method of operating a non-volatile semiconductor device.

2. Description of the Related Art

So-called flash memory is one common type of non-volatile memory. The flash memory device writes or erases data by supplying electrical charge to or removing electrical charge from a charge storage layer via a tunnel insulating layer. When negative charge is accumulated in the charge storage layer of a memory cell in its initial state, a corresponding threshold voltage for the constituent cell transistor increases. Alternately, when negative charge is dissipated from the charge storage layer, the threshold voltage for the cell transistor decreases. Thus, the threshold voltage of the memory cell transistor changes in accordance with the quantity of charge stored in the charge storage layer. The data value (e.g., a logical 0 or 1 in the case of a binary memory cell) ascribed to the memory cell may be determined by detecting a channel current using an arbitrary reading voltage designated between the voltages defining a programming or writing state and an erase state for the memory cell.

An array of non-volatile memory devices includes a plurality of memory cells. The threshold voltages of the constituent memory cells in the memory cell array will vary across a distribution due to a number of reasons. In a case where the difference between a writing threshold voltage and an erase threshold voltage is relatively small, the resulting distribution of memory cell threshold voltages may be insufficient to allow data value determination.

As the commercial demands for non-volatile memory systems having greater data density have increased, single bit memory devices have been replaced by multi-bit memory cells (or a multi-level cells). Greater data density allows miniaturization of the memory system without sacrificing performance. While multi-level cells offer increased data density, they also pose additional difficulties in the bit-value determination process. That is, conventional multi-level cells use a method that divides the maximum range for memory cell threshold voltage into a plurality of intervals. Each data bit value is then ascribed to a particular one of the plurality of threshold voltage levels. The resulting threshold voltage difference between adjacent data bit states is necessarily small. Therefore, it is important to strictly control the threshold voltage distribution in order to secure reliable operation of a memory system incorporating multi-level cells.

Figure (FIG.) 1 is a graph illustrating a typical threshold voltage distribution as well as changes to this distribution caused by (e.g.,) environmental factors. In the graph, the horizontal axis indicates threshold voltage and the vertical axis indicates a corresponding charge distribution. The dotted line indicates a threshold voltage distribution for memory cells having been subjected to an endurance test involving the application of ten thousand writing/erasing cycles. (This type of endurance test is a common reliability marker for non-volatile memory devices). In contrast, the solid line indicates a threshold voltage distribution for memory cells after having been baked for twenty four hours at 150° C. following the application of ten thousand writing/erasing cycles.

Referring to FIG. 1, the respective threshold voltages implicated in the multi-level memory cell threshold voltage distribution may be associated with data state of 00, 01, 10, and 11. Since single level memory cells store only data values of 0 and 1, a relatively wide threshold voltage difference between corresponding data states may be used, as well as relatively wide threshold voltage ranges. In contrast, within multi-level memory cells the differences between various threshold voltages indicating different data states is relatively narrow and distribution of the corresponding threshold voltages must be strictly maintained.

Note that per FIG. 1, the distribution of threshold voltages following ten thousand writing/erasing cycles just allows data states to be discriminated one from another. However, when the memory cells are subsequently baked for twenty four hours at 150° C., the threshold voltages of memory cells shift to skew the distribution of the threshold voltages. Under such conditions, data states discrimination is difficult and may be impossible. Particularly, referring to the specific example illustrated in the graph of FIG. 1, memory cells having threshold voltages that overlap in the definition of data states 01 and 11 are present. Such a condition means that reliability of the corresponding cell transistors can not be deemed acceptable.

FIG. 2 is a conceptual diagram further explaining the threshold voltage shift and a distribution change that results from application of a thermal baking following endurance testing.

Referring to FIG. 2, as a writing/erasing cycle, wherein an electron present on a floating gate (FG) or a substrate (SB) tunnels through a tunnel insulating layer (Tox), is repeated, a defect may be generated in the tunnel insulating layer (Tox) and an electron may become trapped in-the defect. The number of electrons trapped in the tunnel insulating layer (Tox) is not constant for each memory cell, but a distribution of threshold voltages can be reduced by means of a verification operation performed after writing and erase operations. However, when memory cells having a normal distribution are baked, electrons trapped in the tunnel insulating layer (Tox) are liberated by the applied thermal energy so the threshold voltage of the memory cell shifts and the distribution of threshold voltages changes (e.g., increases). This type of threshold distribution change may result in the erroneous interpretation of stored data and reduced reliability of memory cells.

### SUMMARY OF THE INVENTION

Embodiments of the invention provide a method for removing electrons trapped in a tunnel insulating layer in order to minimize a threshold voltage shift and a threshold voltage distribution change generated by subsequent liberation of the trapped electrons.

Embodiments of the invention provide a method for operating a non-volatile memory device which is capable of reducing the number of electrons accumulated in a tunnel insulating layer during repeated writing/erasing cycle testing. Embodiments of the invention also provide a method of removing trapped electrons using recombination of such with an injecting hole.

In one embodiment, the invention provides a method for operating a non-volatile memory device having a memory cell including a channel region separating a source region and a drain region, a tunnel insulating layer, a charge storage layer, and a gate electrode formed over the channel region, the method comprising; applying a negative voltage to the gate electrode and applying a positive voltage to at least one of the source and drain regions to inject holes into the tunnel insulating layer and thereby remove electrons trapped in the tunnel insulating layer.

In another embodiment, the invention provides a method for operating a non-volatile memory device comprising; performing a write operation to supply electrons to the charge storage layer, performing an erase operation to remove electrons stored in the charge storage layer, performing a hole injection process to inject the holes into the tunnel insulating layer after the erase operation, and performing a post program operation to supply electrons to the charge storage layer to initialize an over-erased memory cell.

In a related embodiment, the method for operating a non-volatile memory device comprises; performing a write operation to supply electrons to the charge storage layer, performing an erase operation to remove electrons stored in the charge storage layer, performing a post program operation to supply electrons to the charge storage layer to initialize an over-erased memory cell, and performing a hole injection process to inject the holes into the tunnel insulating layer after the post program operation.

In another related embodiment, the method for operating a non-volatile memory device comprises; iteratively and sequentially performing a write operation to supply electrons to the charge storage layer, a hole injection process to inject the holes into the tunnel insulating layer after the post program operation, and a verifying operation to determine the level of a threshold voltage, performing an erase operation to remove electrons stored in the charge storage layer, and performing a post program operation to supply electrons to the charge storage layer to initialize an over-erased memory cell.

### BRIEF DESCRIPTION OF THE FIGURES

FIG. 1 is a graph illustrating a threshold voltage distribution in a non-volatile memory device according to a conventional art;

FIG. 2 is a view explaining a reason of a threshold voltage distribution in a non-volatile memory device according to a conventional art;

FIGS. 3 and 4 are cross-sectional views explaining a method for operating a non-volatile memory device according to a preferred embodiment of the present invention;

FIGS. 5 to 7 are flowcharts illustrating a method for operating a non-volatile memory device according to the present invention;

FIGS. 8 and 9 are views explaining a method for operating a non-volatile memory device according to an embodiment of the present invention; and

FIG. 10 is a graph illustrating a change in a threshold voltage when a memory cell is baked for twelve hours at 150° C. after data is written in the memory cell.

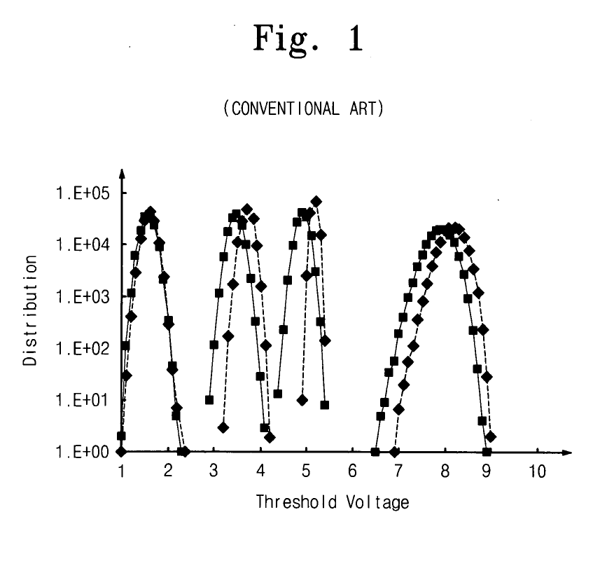

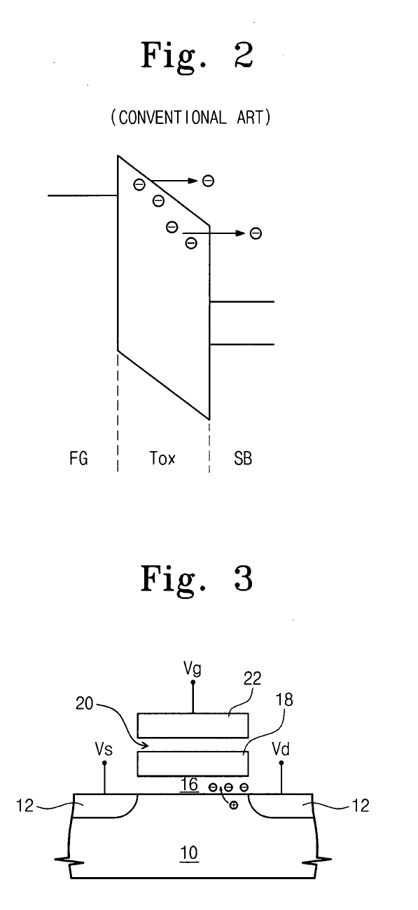

### DESCRIPTION OF EMBODIMENTS

Embodiments of the invention will be described below in some additional detail with reference to the accompanying drawings. The present invention may, however, be embodied in many different forms and should not be constructed as being limited to only the embodiments set forth herein. Rather, these embodiments are presented as teaching examples.

In the figures, the dimensions of various layers and regions may have been exaggerated for purpose of clarity. It will also be understood that when a layer (or film) is referred to as being ‘on’ another layer or substrate, it can be directly on the other layer or substrate, or intervening layers may also be present. Throughout the drawings and the specification, like reference numerals refer to like or similar elements.

FIG. 3 is a schematic view illustrating a process of removing electrons trapped in a tunnel insulating layer through the injection of holes.

Referring to FIG. 3, the non-volatile memory device includes a source region 12 and a drain region 14 formed in a semiconductor substrate 10. A channel region is defined between source and drain regions 12 and 14. A tunnel insulating layer 16, a charge storage layer 18, a blocking insulating layer 20, and a control gate electrode 22 are stacked on the channel region. Charge storage layer 18 can be a floating gate, a charge trap insulating layer, or an insulating layer having metal or silicon nano crystal therein. Also, the blocking layer can include a high dielectric layer such as a silicon oxide layer, a silicon nitride layer, and a metal oxide layer.

Generally speaking, the writing (i.e., programming) and erase operations associated with common types of non-volatile memory devices are performed using a physical phenomenon known as Fowler-Nordheim (FN) tunneling or another physical phenomenon known as hot carrier injection. During either of these processes, electrical carriers (electron and/or holes) move through tunnel insulating layer 16.

As noted above, after the application of many writing/erasing cycles, defects may form in tunnel insulating layer 16. Electrons passing through tunnel insulating layer 16 that do not reached semiconductor substrate 10 or charge storage layer 18 are said to be “trapped.” Electrons are commonly trapped as a result of defects that exhibit low energy states and cause accumulation of electrons in tunnel insulating layer 16. The quantity of charge accumulated in tunnel insulating layer 16 will vary from memory cell to memory across a memory cell array in relation to various factors such as the number of applied writing/erase operations, and deviations in physical properties and structure of associated regions and layers. As noted above, the trapped electrons accumulated in the tunnel insulating layer may be liberated due to environmental changes (such as applied thermal energy). Once liberated, these electrons tend to shift the threshold voltages of memory cells whose distribution ought to be carefully controlled. As a result of threshold voltage shifting, the corresponding distribution increases gradually and data states for the implicated memory cells may be changed.

Embodiments of the invention provide a method for suppressing this shift and a distribution increase of threshold voltages in operating circumstances where data states should be maintained. In one embodiment, the method comprises removing electrons accumulated in tunnel insulating layer 16 during writing/erasing cycle(s).

The electrons accumulated in tunnel insulating layer 16 may be removed by allowing the electrons to recombine with holes. A deep depletion layer is formed in at least one of source region 12 and drain region 14, and holes generated by band to band tunneling (BTBT) in this region may be injected into tunnel insulating layer 16. For example, a sufficiently negative voltage may be applied to the control gate electrode Vg such that a negative potential is induced across tunnel insulating layer 16, thereby accumulating holes at the surface of semiconductor substrate 10. Thereafter, a sufficiently positive voltage may be applied to drain region 14 to induce band to band tunneling in the deep depletion layer.

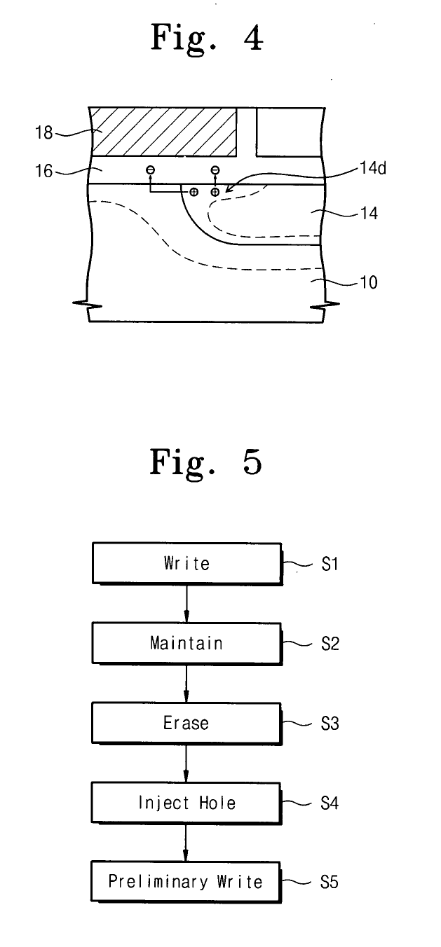

Referring to FIG. 4, a deep depletion layer 14d is formed in a portion of drain region 14 that under-laps tunnel insulating layer 16. The BTBT is induced in deep depletion layer 14d due to reduction of a band width. Holes generated by the BTBT are injected into tunnel insulating layer 16 by an applied gate voltage, or are diffused in a lateral direction and injected into tunnel insulating layer 16 by a gate voltage applied to the channel region. Holes generated by the BTBT obtain energy from a negative gate voltage and become hot carriers (i.e., highly energized carrier) that may be readily injected to tunnel insulating layer 16. Once a hole is injected into tunnel insulating layer 16 it recombines with a trapped electron to effectively remove the electron from tunnel insulating layer 16.

According to embodiments of the invention, as the number of electrons trapped and accumulated in tunnel insulating layer 16 is reduced in this manner, so to is the number of electrons potentially liberated by application of thermal energy (e.g., by a subsequently applied high temperature baking process).

Holes generated by the BTBT remove electrons trapped inside a portion of the tunnel insulating layer that overlaps the drain region 14, and a portion of the tunnel insulating layer that is located on the channel region in the neighborhood of the drain region 14. When a non-volatile memory device is highly integrated and a channel length is reduced to a nano scale, electrons can be removed from a portion of a tunnel insulating layer that is located on an entire channel region.

Though a positive voltage has been exemplarily applied to drain region 14 in the foregoing embodiments, electrons trapped inside tunnel insulating layer 16 adjacent to source region 12 may be removed by application of a positive voltage to source region 12 as well as the drain region 14.

Operation of a non-volatile memory device includes a writing (programming) operation and an erase operation. Initially, the non-volatile memory device is set to an initial threshold voltage, and data is recorded through application of writing and erase operations. The erase operation applied to a non-volatile memory device is commonly performed on a block unit or sector unit basis. Since a plurality of memory cells are erased simultaneously, the threshold voltages of the erased memory cells show a distinct probability distribution. Data may be distorted when a memory cell is over-erased to less than its predetermined threshold voltage. The possibility of an over-erased memory cell may result in a decision to increase a threshold voltage distribution when data is subsequently written. Therefore, a “post program” or preliminary write operation for verifying the threshold voltage of a memory cell and raising the threshold voltage of a memory cell in an over-erased state to at least a predetermined value is required.

FIGS. 5 to 7 are flowcharts illustrating methods of reducing the number of electrons accumulated in a tunnel insulating layer during operation of a non-volatile memory device, according to embodiments of the invention.

Referring to FIG. 5, hole injection is performed after an erase operation, but before a post program operation in order to reduce the number of electrons accumulated in the tunnel insulating layer. First a write (programming) operation is performed (S1). A retention period, during which the written data is maintained (S2) and during which a read operation is performed, is provided after the write operation. Thereafter, an erase operation (S3) is performed.

The number of electron loss in a charge storage layer may be managed during the retention period (S2). That is, during the retention period (S2), the threshold voltage of a memory cell indicates an electrical charge value that accounts for any electrons trapped in the tunnel insulating layer. Since the number of trapped electrons may differ for each memory cell, the distribution of threshold voltages when trapped electrons are liberated. To prevent this threshold voltage distribution increase, the illustrated embodiment of the invention injects holes (S4) following the erase operation (S3) before performing a post program operation (S5) in order to reduce or minimize the number of electrons that exist in the tunnel insulating layer during the retention period (S2). As described above, holes generated by BTBT may be injected into the tunnel insulating layer in the vicinity of the source region and/or the drain region.

When the hole injection (S4) is performed following the erase operation (S3), the change in a threshold voltage due to electron loss is previously reflected so that a distribution of threshold voltages in memory cells can be managed to a predetermined width or less after the post program operation (S5).

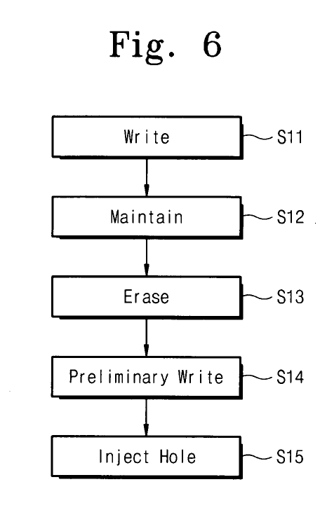

FIG. 6 is a flowchart explaining a method for reducing or minimizing the accumulation of electrons inside a tunnel insulating layer according to another embodiment of the invention.

Referring to FIG. 6, like the previous embodiment, hole injection is used as a technique to minimize the number of trapped electrons during a retention period (S12). However, the hole injection process (S15)is performed after a post program operation (S14) but before a next program operation (S11).

When the hole injection is performed between the erase operation (S13) and the post program operation (S14), there is an advantage that the threshold voltage of the memory cells on which the post program operation has been performed reflects removal of electrons by the hole injection. On the other hand, when the hole injection (S15) is performed after the post program operation (S14), the threshold voltage of the memory cell on which the post program operation has been performed may change due to the hole injection (S15). However, when holes are injected after the post program operation (S14) but before a verify operation, it may be determined whether the threshold voltage has shifted, and distribution of threshold voltages may be reduced by adding a post program pulse.

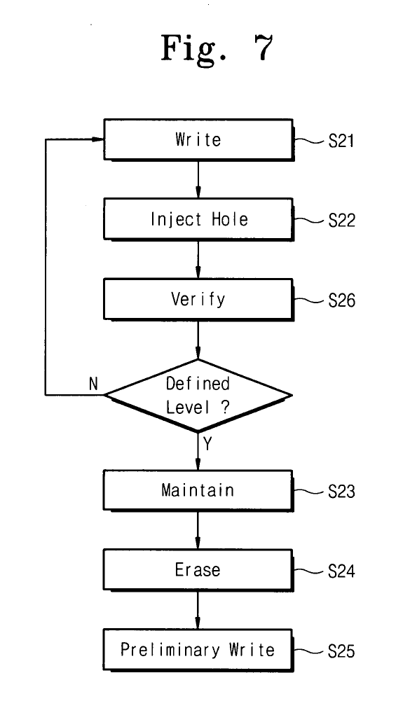

FIG. 7 is a flowchart explaining a method of reducing or minimizing the accumulation of electrons inside a tunnel insulating layer according to yet another embodiment of the invention.

Referring to the embodiment illustrated in FIG. 7, hole injection is performed after the write operation (S21). When the hole injection is performed after the write operation (S21), there is a disadvantage that the threshold voltage of a memory cell on which the write operation has been performed is shifted. Generally, a write operation is repeatedly applied to a non-volatile memory device and thereafter a verifying operation is performed to adjust the threshold voltage of a memory cell to a required level. Therefore, trapped electrons are removed by the hole injection (S22) process after the write operation (S21). The threshold voltage may then be checked during the verifying operation. When the verifying operation determines that the threshold voltage is low, the write operation (S21), hole injection (S22), and associated verifying operation may be repeated as necessary to adjust the write threshold voltage to a defined value.

Thereafter the retention period (S23), the erase operation (S24) and the post program operation (S25) may be performed.

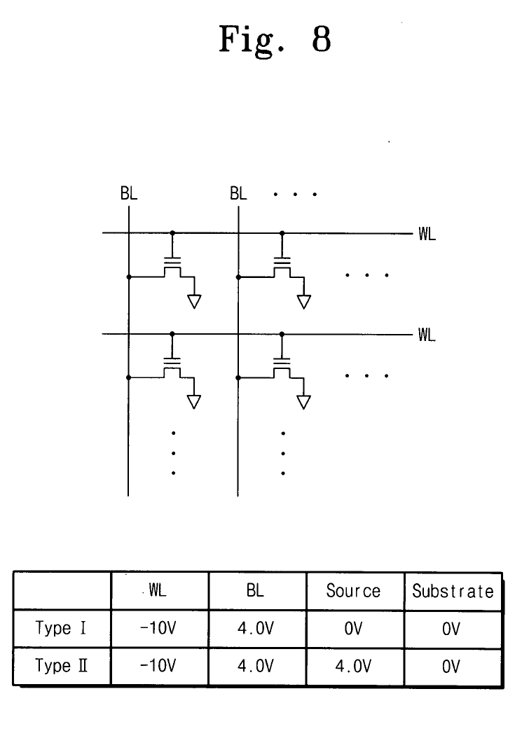

Any one of the foregoing methods may be applied to a non-volatile memory device including both single bit memory cells or multi-level memory cells, and to non-volatile memory cells of various types, structures and architectures. For example, FIG. 8 is a view explaining an exemplary method of removing electrons trapped in a tunnel insulating layer of a non-volatile memory device having a NOR type cell array structure.

Referring to FIG. 8, the NOR type cell array includes a plurality of memory cells arranged a row direction and a column direction, a word line (WL) where gate electrodes of the memory cells are connected in a row direction, and a bit line (BL) where drain regions of the memory cells are connected in a column direction. A source region of each memory cell is connected to a common source line and grounded or floated in general.

Hole injection of a NOR type memory cell array can be classified into a type I hole injection and a type 11 hole injection. In the type I hole injection, holes generated by the BTBT in a deep depletion layer of a drain region are injected into a tunnel insulating layer to remove trapped electrons. In the type 11 hole injection, holes generated in a deep depletion layer of a source region and a drain region are injected to remove trapped electrons.

Referring to FIG. 8, −10 V is applied to a selected WL, 4 V to a selected BL, and 0 V to a source region and a substrate according to the type I hole injection. At this point, holes are generated by the BTBT in a deep depletion layer of the drain region illustrated in FIG. 4, and pulled and injected by a negative potential applied to the tunnel insulating layer into the tunnel insulating layer to remove trapped electrons. When the channel length of a cell transistor is sufficiently short, the holes generated by the BTBT are diffused in a lateral direction along the channel region, and can recombine with trapped electrons in a portion of the tunnel insulating layer that is formed over the entire channel region by a vertical electric field.

Since holes are generated from both the source region and the drain region in the type 11 hole injection, probability that the holes recombine with the trapped electrons inside the tunnel insulating layer over the entire channel region increases even more. Here, −10 V is applied to a selected WL, 4 V to a selected BL and a source region, and 0 V to a substrate according to the type 11 hole injection. At this point, holes are generated by the BTBT in a deep depletion layer of the drain region and the source region, and pulled and injected by a negative potential applied to the tunnel insulating layer into the tunnel insulating layer to remove trapped electrons.

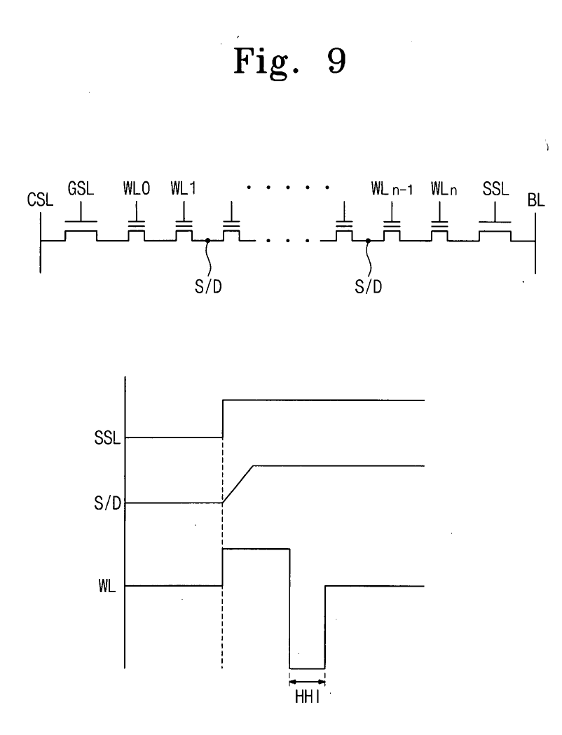

FIG. 9 is a view explaining an exemplary method of removing trapped electrons inside a tunnel insulating layer in a non-volatile memory device having a NAND type cell array structure.

Referring to FIG. 9, the NAND type cell array includes a ground selecting transistor having a source region connected to a common source line (CSL), and a string selecting transistor having a drain region connected to a bit line (BL). A plurality of cell transistors is arranged between a drain region of the ground selecting transistor and a source region of the string selecting transistor. Source regions are connected with drain regions in series in the cell transistors.

The ground selecting transistors and string selecting transistors connected in series, and cell transistors constitute a cell string. The NAND type cell array includes a plurality of cell strings. A gate electrode of the ground selecting transistor is connected to a ground selecting line (GSL), a gate electrode of the string selecting transistor is connected to a string selecting line (SSL), and a gate electrode of the cell transistor is connected to a WL.

Also in a NAND type cell array, holes generated by the BTBT in a deep depletion layer of the source region and/or drain region are injected into a tunnel insulating layer to remove trapped electrons. A positive pass voltage should be applied to other memory cell of the cell string in order to apply a positive voltage to a source region or a drain region of a selected memory cell in a NAND type cell array structure. Therefore, an operation different from that of a NOR type memory cell is required in order to apply a negative voltage to a gate electrode and apply a negative voltage to a source region or a drain region. First, a voltage Vcc is applied to a BL and an SSL, and a positive pass voltage is applied to a WL in order to apply a positive voltage to the source region and the drain region of the cell string. The voltage Vcc applied to the BL is delivered through a string selecting transistor and a cell transistor to boost the source region and the drain region of the cell string to a predetermined positive voltage. When the voltage Vcc is applied to the CSL and the GSL, all source regions and drain regions of the cell string can be boosted to a positive voltage.

A negative voltage is transiently applied to a WL after the source region and/or drain region are boosted in order to convert the surface of a channel region of the cell transistor into an accumulation state. Holes generated at the source region and/or the drain region are injected into the tunnel insulating layer to remove trapped electrons through recombination with the electrons during this period.

It can be considered that the string selecting transistor and the BL are maintained at Vcc while holes are injected, or 0 V is applied to gate electrodes of the ground selecting transistor and the string selecting transistor to block a channel. Since hot hole injection (HHI) pulse is short (about several μs), this period is sufficient for holes to be injected even when a voltage potential applied to the source region and/or a drain region is gradually reduced during this period.

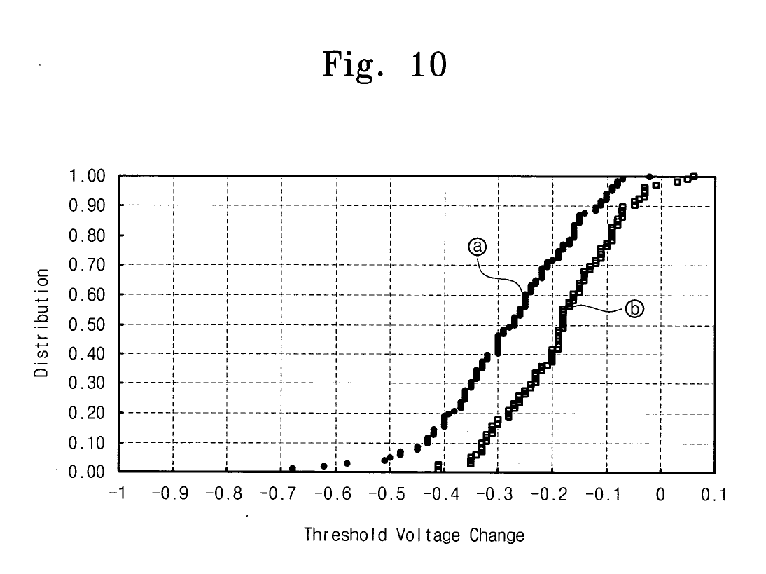

FIG. 10 is a graph illustrating a change in a threshold voltage for memory cells baked for twelve hours at 150° C. after a program operation is performed. The illustrated data is taken from an experiment performed on a NOR type memory cell following application of ten thousand writing/erasing cycles. A program operation is performed at a voltage of 7.8 V, a BL voltage of 4.0 V, a hot carrier injection time of 1 μs, an erase operation is performed at 18 V, and an FN tunneling is performed for 50 ms. In the graph, a line \textcircled{a} illustrates results of memory cells where trapped electrons have not been removed, and a line \textcircled{b} illustrates results of memory cells where trapped electrons have been removed.

Referring to FIG. 10, trapped electrons are emitted during a baking process, so that a threshold voltage drastically changes in memory cells according to a conventional operating method. On the contrary, the number of trapped electrons is considerably reduced and thus the number of electrons emitted during a baking process is relatively small for memory cells operated in accordance with an embodiment of the invention. Referring to the graph of FIG. 10, a change in a threshold voltage following a baking process according to an embodiment of the invention is reduced by about 1 V in comparison with a conventional art.

According to embodiments of the invention, the number of electrons accumulated in a tunnel insulating layer is remarkably reduced during the application of writing/erasing cycle testing. Accordingly, a non-volatile memory device having improved reliability with little data change can be provided.

The benefits of the foregoing embodiments are not limited to any particular type of memory cell structure, although several possible examples have been given. This result arises from the fact that the increased reliability is secured by changing the method of operation for the non-volatile memory device and not by some particular structural limitation of the non-volatile memory device.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A method for operating a non-volatile memory device having a memory cell including a channel region separating a source region and a drain region, a tunnel insulating layer, a charge storage layer, and a gate electrode formed over the channel region, the method comprising:
applying a negative voltage to the gate electrode and applying a positive voltage to at least one of the source and drain regions to inject holes into the tunnel insulating layer and thereby remove electrons trapped in the tunnel insulating layer.

2. The method of claim 1, wherein the negative voltage applied to the gate electrode is lower than a voltage under which holes perform tunneling through the tunnel insulating layer.

3. The method of claim 2, wherein the negative voltage applied to the gate electrode is lower than a voltage under which holes perform Fowler-Nordheim tunneling through the tunnel insulating layer.

4. The method of claim 1, wherein the method for operating a non-volatile memory device comprises:
performing a write operation to supply electrons to the charge storage layer;
performing an erase operation to remove electrons stored in the charge storage layer;
performing a hole injection process to inject the holes into the tunnel insulating layer after the erase operation; and
performing a post program operation to supply electrons to the charge storage layer to initialize an over-erased memory cell.

5. The method of claim 1, wherein the method for operating a non-volatile memory device comprises:
performing a write operation to supply electrons to the charge storage layer;
performing an erase operation to remove electrons stored in the charge storage layer;
performing a post program operation to supply electrons to the charge storage layer to initialize an over-erased memory cell; and
performing a hole injection process to inject the holes into the tunnel insulating layer after the post program operation.

6. The method of claim 1, wherein the method for operating a non-volatile memory device comprises:
iteratively and sequentially performing a write operation to supply electrons to the charge storage layer, a hole injection process to inject the holes into the tunnel insulating layer after the post program operation, and a verifying operation to determine the level of a threshold voltage;
performing an erase operation to remove electrons stored in the charge storage layer; and
performing a post program operation to supply electrons to the charge storage layer to initialize an over-erased memory cell.

7. The method of claim 1, wherein the non-volatile memory device has a NOR type cell structure including a wordline connected to the gate electrode, a bit line connected to the drain region, and a common source line connected to the source region, and
wherein the negative voltage is applied to the wordline, and the positive voltage is applied to a bit line during the injecting of the holes into the tunnel insulating layer.

8. The method of claim 1, wherein the non-volatile memory device has a NOR type cell structure including a wordline connected to the gate electrode, a bit line connected to the drain region, and a common source line connected to the source region, and
wherein the negative voltage is applied to the wordline, and the positive voltage is applied to the bit line and the common source line during the injecting of the holes into the tunnel insulating layer.

9. The method of claim 1, wherein the non-volatile memory device has a NAND type cell structure including;
a common source line and a bit line, wherein a source region of a first selecting transistor is connected to the common source line and a drain region of a second selecting transistor is connected to the bit line,
a memory cell having a source region and a drain region connected in series between a drain region of the first selecting transistor and a source region of the second selecting transistor;
a wordline, a ground selecting line, and a string selecting line connected to the memory cell, a gate electrode of the first selecting transistor, and a gate electrode of the second selecting transistor, respectively, and
wherein the positive voltage is first applied to the wordline, the positive voltage is applied to the string selecting line and the bit line to boost the source region and drain region of the memory cell to a positive voltage, and thereafter switching the positive voltage applied to the wordline to a negative voltage in order to inject the holes into the tunnel insulating layer.

10. The method of claim 9, wherein as the voltage applied to the wordline switches from a positive voltage to a negative voltage, the first and second selecting transistors are turned OFF.

11. The method of claim 1, wherein the memory cell is a multi-level memory cell.

12. The method of claim 11, wherein the multi-level memory cell stores at least 2 data bits.
